(19) United States
(12) Patent Application Publication
(10) Pub. No.: US 2009/0146168 A1
(43) Pub. Date: Jun. 11, 2009

(54) HIGH EFFICIENCY LED WITH MULTI-LAYER REFLECTOR STRUCTURE AND METHOD FOR FABRICATING THE SAME

(75) Inventors: Young-Se Kwon, Daejon (KR); Jae-Ho Kim, Daejeon (KR)

Correspondence Address: GIFFORD, KRASS, SPRINKLE,ANDERSON & CITKOWSKI, P.C, PO BOX 7021, TROY, MI, 48007-7021, US

(73) Assignees: Wavenics Inc., Daejeon (KR); Korea Advanced Institute of Science and Technology, Daejon (KR)

(21) Appl. No.: 12/297,889

(22) PCT Filed: Jul. 7, 2006
(86) PCT No.: PCT/KR06/02667

§ 371 Date: Oct. 21, 2008

(30) Foreign Application Priority Data
Apr. 21, 2006 (KR) 10-2006-0036057

(51) Int. Cl. H01L 33/00; H01L 21/3065; H01L 21/308

(52) U.S. Cl. 257/98; 438/46; 257/E21.218; 257/E33.013; 257/E21.232

(57) ABSTRACT

Provided are a high efficiency light emitting diode and a method for fabricating the same, in which a multi-layer reflector is laminated to a surface emission type light emitting diode to improve the efficiency of a light emitting diode. A high efficiency reflector is integrated on the light emitting diode using a dry etching process and a wet etching process. Although light produced from an active layer when applying a current thereto is emitted in several directions, the reflectors formed both sides of the active layer reflect the emitted light toward a surface of a semiconductor substrate, thus improving the light efficiency. Compared with the existing light emitting diode, the structure of the proposed light emitting diode is more efficient and therefore it can be used as a light source having low power consumption and high brightness. Also, the light emitting diode can be fabricated using the existing semiconductor process, thus reducing the complexity of the fabricating process.

### TECHNICAL FIELD

The present invention relates to a semiconductor light emitting diode, and more particularly, to a light emitting diode with multi-layer reflector structure for improving its luminous efficiency and a method for fabricating the same.

### BACKGROUND ART

Light emitting diodes (LEDs) as a luminous object have a variety of applications such as an optical communication or a display device, and are mainly manufactured based on GaAs, InP, GaN or the combination thereof.

LEDs are classified as surface emission type LEDs and edge emission type LEDs, depending on the methods of emitting light produced from an emission region to the outside. The surface emission type LED has a structure to emit light in a direction perpendicular to a junction surface. The surface emission type LED is particularly advantageous to provide high efficiency because light produced from an active layer is emitted outside without a self absorption loss.

In such a conventional surface emission type LED, however, the light refractive index of a material of the LED is greater than that of air of the outside to which light is emitted, regardless of the material of the LED. Therefore, due to a total reflection, only the light incident at an angle less than a specific angle with respect to the surface is emitted to the outside.

Generally, an LED chip has a section of a rectangular parallelepiped shape. In this case, the incident angle of light which is not emitted outside is not changed even through infinite reflections, thus decreasing the efficiency thereof.

### DISCLOSURE OF INVENTION

### Technical Problem

Accordingly, an object of the present invention is to provide a high efficiency LED with multi-layer reflector structure for improving a luminous efficiency and a method for fabricating the same.

### Technical Solution

According to an aspect of the present invention, there is provided a high efficiency light emitting diode including: a compound semiconductor substrate with convex-concave portions symmetrical with respect to a first surface; an active layer disposed between the convex-concave portions over the compound semiconductor substrate; a p-type semiconductor layer disposed between the convex-concave portions on the active layer; an anode disposed between the convex-concave portions on the p-type semiconductor layer; an insulation layer formed along a profile of the first surface including the convex-concave portions on the semiconductor substrate, excluding an upper surface of the anode; a reflective layer disposed on the anode and an inclined surface of the insulation layer adjacent to the anode; and a cathode disposed on an edge of a second surface opposing to the first surface of the semiconductor substrate.

One or more reflective layers may be provided.

The reflective layer may be formed on a portion of the inclined surface of the insulation layer or may not be formed on the inclined surface of the insulation layer.

According to another aspect of the present invention, there is provided a method for fabricating a high efficiency light emitting diode, including: preparing a compound semiconductor substrate; sequentially forming an active layer and a p-type semiconductor layer on a surface of the compound semiconductor substrate; forming an anode on a predetermined portion of the p-type semiconductor layer; forming a masking pattern including a first masking pattern and a second masking pattern, the first masking pattern having a stepped configuration covering the anode, the second masking pattern being spaced apart from the first masking pattern to partially cover the p-type semiconductor layer; dry etching the masking pattern, the active layer, the p-type semiconductor layer and the semiconductor substrate, such that the masking pattern has a predetermined thickness; and wet etching the resulting structure to provide a smooth multi-layer convex-concave reflector having a stepped configuration around the anode.

The masking pattern may be formed of a silicon nitride layer, a silicon oxide layer, or a combination thereof.

The dry etching process may be performed in a plasma etching apparatus using a chlorine (Cl₂) gas, a hydrobromide (HBr) gas, or a combination thereof, the plasma etching apparatus including a Reactive Ion Etching (RIE) apparatus, a Reactive Ion Beam Etching (RIBE) apparatus, and an Inductive Coupled Plasma (ICP) apparatus.

The wet etching process may be performed using one selected from the group consisting of a mixture solution of HBr+H₃PO₄+K₂Cr₂O₇, a mixture solution of HBr+H₂O₂+H₂O, and a mixture solution of Br₂+methanol.

### Advantageous Effects

In the high efficiency LED and the method for fabrication the same according to the present invention, the structure of the LED is more efficient than the conventional LED and therefore it can be used as a light source having low power consumption and high brightness. Also, the LED can be fabricated using the existing semiconductor process, thus reducing the complexity of the fabricating process.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a sectional view showing a structure of an LED according to an embodiment of the present invention; and

FIGS. 2 to 4 are sectional views illustrating a method for fabricating the LED of FIG. 1.

### BEST MODE FOR CARRYING OUT THE INVENTION

The present invention will now be described in detail with reference to the accompanying drawings. It will be apparent to those skilled in the art that various modifications and variations can be made in the embodiments of the present invention, and the scope of the present invention should not be construed as being limited to the embodiments set forth herein. Those skilled in the art can understand the present invention more fully through the embodiments set forth herein. In the drawings, the shapes of elements are exaggerated for clarity. The same reference numerals will be used throughout the drawings to refer to the same or like parts.

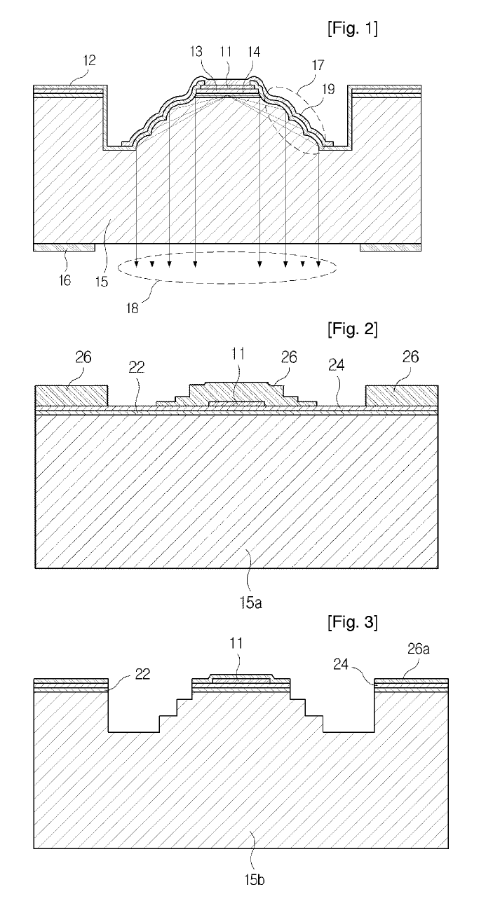

FIG. 1 is a sectional view showing a high efficiency LED according to an embodiment of the present invention.

Referring to FIG. 1, the high efficiency LED according to the embodiment of the present invention includes: a compound semiconductor substrate 15 with convex-concave portions 17 symmetrical with respect to a first surface; an active layer 14 disposed between the convex-concave portions 17 over the compound semiconductor substrate 15; a p-type semiconductor layer 13 disposed between the convex-concave portions 17 on the active layer 14; an anode 11 disposed between the convex-concave portions 17 on the p-type semiconductor layer 13; an insulation layer 12 formed along a profile of the first surface including the convex-concave portions 17 on the semiconductor substrate 15, but excluding an upper surface of the anode 11; a reflective layer 19 disposed on the anode 11 and an inclined surface of the insulation layer 12 adjacent to the anode 11; and a cathode 16 disposed on an edge of a second surface opposing to the first surface of the semiconductor substrate 15.

The LED shown in FIG. 1 includes the convex-concave portions 17 having the reflective layer 19 and the insulation layer 12 configured in the stepped convex-concave shape. When a voltage is applied to the anode 11 and the cathode 16, the convex-concave portions 17 reflects light emitted from the active layer 14, thereby increasing light efficiency. In other words, the convex-concave portions 17 can further reflect the light emitted at an angle less than a critical angle, thereby improving an entire light efficiency.

Even though three reflective layers 19 are provided in the above embodiment, the number of the reflective layers 19 may increase or decrease depending on characteristics and production cost of the desired device.

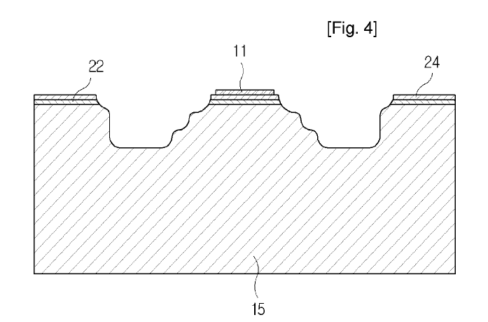

A method for fabricating the LED of FIG. 1 will be described below with reference to FIGS. 2 to 4.

Referring to FIG. 2, a compound semiconductor substrate 15a such as a GaAs substrate or an InP substrate is prepared. An active layer 22 and a p-type semiconductor layer 24 are formed on a first surface, that is, an upper surface of the semiconductor substrate 15a. An anode 11 is formed on a predetermined portion of the p-type semiconductor layer 24. Then, a masking material 26 is applied on the anode 11 and p-type semiconductor 24, and a stepped masking pattern 26 is formed on and around the anode 11 using a semiconductor lithograph process and a dry etching process.

The masking material 26 may be a silicon nitride (SiNₓ) layer, a silicon oxide (SiO₂) layer or a combination thereof.

Referring to FIG. 3, the resulting structure is dry etched using a chlorine (Cl₂) gas, a hydrobromide (HBr) gas, or a combination thereof. The etching process is performed until the masking pattern 26 remains to a predetermined thickness. The masking pattern 26, the p-type semiconductor layer 24, the active layer 22 and the semiconductor substrate 15a thereunder that are exposed by the dry etching process are etched to form a stepped configuration as illustrated in FIG. 3.

A dry etching apparatus may include plasma etching apparatus such as a Reactive Ion Etching (RIE) apparatus, a Reactive Ion Beam Etching (RIBE) apparatus, an Inductive Coupled Plasma (ICP) apparatus, and the like, which is generally used for a semiconductor process. In the case where the dry etching process is performed using a chlorine gas or a hydrobromide gas, a GaAs or an InP is etched ten times faster than a silicon nitride layer or a silicon oxide layer. Thus, the stepped configuration formed on the semiconductor substrate is extended lengthwise in the structure shown in FIG. 2. In consideration of this, the thickness of the stepped configuration is determined in a dry etching process.

Referring to FIG. 4, the resulting structure provided by the drying etching process of FIG. 3 is wet etched and the exposed surface is polished, thereby providing the multi-layer reflector structure. A wet etching solution having the above characteristics with respect to GaAs or InP includes a mixture solution of HBr+H3PO4+K₂Cr₂O₇, a mixture solution of HBr+H₂O₂+H₂O, or a mixture solution of Br₂+methanol.

While the invention has been shown and described with reference to a certain preferred embodiment thereof, it will be understood by those skilled in the art that various changes in form and details may be made therein without departing from the spirit and scope of the invention as defined by the appended claims.

1. A high efficiency light emitting diode comprising:
a compound semiconductor substrate with convex-concave portions symmetrical with respect to a first surface;
an active layer disposed between the convex-concave portions over the compound semiconductor substrate;
a p-type semiconductor layer disposed between the convex-concave portions on the active layer;
an anode disposed between the convex-concave portions on the p-type semiconductor layer;
an insulation layer formed along a profile of the first surface including the convex-concave portions on the semiconductor substrate, excluding an upper surface of the anode;
a reflective layer disposed on the anode and an inclined surface of the insulation layer adjacent to the anode; and
a cathode disposed on an edge of a second surface opposing to the first surface of the semiconductor substrate.

2. The high efficiency light emitting diode of claim 1, wherein one or more reflective layers are provided.

3. The high efficiency light emitting diode of claim 1, wherein the reflective layer is formed on a portion of the inclined surface of the insulation layer or is not formed on the inclined surface of the insulation layer.

4. A method for fabricating a high efficiency light emitting diode, comprising:
preparing a compound semiconductor substrate;
sequentially forming an active layer and a p-type semiconductor layer on a surface of the compound semiconductor substrate;
forming an anode on a predetermined portion of the p-type semiconductor layer;
forming a masking pattern including a first masking pattern and a second masking pattern, the first masking pattern having a stepped configuration covering the anode, the second masking pattern being spaced apart from the first masking pattern to partially cover the p-type semiconductor layer;
dry etching the masking pattern, the active layer, the p-type semiconductor layer and the semiconductor substrate, such that the masking pattern has a predetermined thickness; and
wet etching the resulting structure to provide a smooth multi-layer convex-concave reflector having a stepped configuration around the anode.

5. The method of claim 4, wherein the masking pattern is formed of a silicon nitride layer, a silicon oxide layer, or a combination thereof.

6. The method of claim 4, wherein the dry etching process is performed in a plasma etching apparatus using a chlorine (Cl₂) gas, a hydrobromide (HBr) gas, or a combination thereof, the plasma etching apparatus including a Reactive Ion Etching (RIE) apparatus, a Reactive Ion Beam Etching (RIBE) apparatus, and an Inductive Coupled Plasma (ICP) apparatus.

7. The method of claim 4, wherein the wet etching process is performed using one selected from the group consisting of a mixture solution of HBr+H₃PO₄+K₂Cr₂O₇, a mixture solution of HBr+H₂O₂+H₂O, and a mixture solution of Br₂+methanol.
